(19) United States
(12) Patent Application Publication
(10) Pub. No.: US 2007/0155092 A1
(43) Pub. Date: Jul. 5, 2007

(54) Method for forming a tip

(75) Inventors: Hsiang-Tai Lu, Hsinchu (TW); Cheng-Hsiung Kuo, Hsinchu (TW); Yue-Der Chih, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/319,357

(22) Filed: Dec. 29, 2005

(51) Int. Cl. H01L 21/336; H01L 21/3205

(52) U.S. Cl. 438/257; 438/593; 438/260

(57) ABSTRACT

A method for forming a tip is disclosed. A layer is formed overlying a substrate. A mask layer is formed overlying the layer. The mask is patterned to form a mask pattern comprising an inner portion and an outer portion, wherein the inner portion is surrounded by the outer portion. The layer uncovered by the mask pattern is treated to form a reaction mask, wherein at least one portion of the reaction mask connect to form a tip of the layer under the inner portion of the mask pattern.

### BACKGROUND

The invention relates to tip formation, and in particular to a method for forming a poly tip of a semiconductor device.

Complementary metal oxide semiconductor (CMOS) memory is generally categorized into random access memory (RAM) and read only memory (ROM). RAM is a volatile memory, wherein the stored data disappears when power is turned off. On the contrary, turning off power does not affect stored data in a ROM.

In the past few years, market share of ROM has been continuously expanding, and the type attracting the most attention has been flash memory. The fact that a single memory cell is electrically programmable and multiple memory cell blocks are electrically erasable allows flexible and convenient application, superior to electrically programmable read only memory (EPROM), electrically erasable programmable read only memory (EEPROM) and programmable read only memory (PROM). Furthermore, fabricating flash memory is cost effective. Having the above advantages, flash memory has been widely applied in consumer electronic products, such as digital cameras, digital video cameras, mobile phones, notebooks, personal stereos and personal digital assistant (PDA).

In a conventional fabrication method of a flash memory, an additional photolithography step is required when forming a contact to a poly gate. Lithography, however, is costly and complicated.

### SUMMARY

These and other problems are generally solved or circumvented, and technical advantages are generally achieved, by preferred illustrative embodiments of the present invention, which provides a method for forming a tip.

An embodiment of the invention provides a method for forming a tip. A layer is formed overlying a substrate. A mask layer is formed overlying the layer. The mask is patterned to form a mask pattern comprising an inner portion and an outer portion, wherein the inner portion is surrounded by the outer portion. The layer uncovered by the mask pattern is treated to form a reaction mask, portions of which connect to form a tip of the layer under the inner portion of the mask pattern.

An embodiment of the invention also provides a method for forming a contact to a gate. A gate layer is formed overlying a substrate, wherein the gate layer comprises a contact portion and a non-contact portion. A mask layer is formed overlying at least the contact portion of the gate layer. The mask layer is patterned to form a mask pattern comprising an outer portion and an inner portion, the inner portion surrounded by the outer portion. The gate layer uncovered by the mask pattern is reacted to form a reaction mask, wherein portions of the reaction mask connect to form a tip of the gate layer under the patterns of the inner portion of the mask pattern.

An embodiment of the invention provides a flash memory. A tunneling dielectric layer is disposed overlying a substrate. A floating gate is disposed overlying the tunneling dielectric layer, wherein the floating gate comprises a contact portion and a non-contact portion, in which the contact portion of the floating gate comprises at least a tip at inner portion of the floating gate. A conductive plug contacts the floating gate at the tip.

### BRIEF DESCRIPTION OF THE DRAWINGS

The invention can be more fully understood by reading the subsequent detailed description in conjunction with the examples and references made to the accompanying drawings, wherein:

FIG. 1A˜FIG. 4C illustrate a method known to the inventor of forming a contact to a ploy gate in a flash memory fabrication.

FIG. 1A is an intermediate plan view of a flash memory.

FIG. 1B is a cross section along line I-I′ of FIG. 1A.

FIG. 1C is a cross section along line II-II′ of FIG. 1A.

FIG. 2A is an intermediate plan view of a flash memory of an embodiment of the invention.

FIG. 2B is a cross section along line I-I′ of FIG. 2A.

FIG. 2C is a cross section along line II-II′ of FIG. 2A.

FIG. 3A is an intermediate plan view of a flash memory of an embodiment of the invention.

FIG. 3B is a cross section along line I-I′ of FIG. 3A.

FIG. 3C is a cross section along line II-II′ of FIG. 3A.

FIG. 4A is an intermediate plan view of a flash memory of an embodiment of the invention.

FIG. 4B is a cross section along line I-I′ of FIG. 4A.

FIG. 4C is a cross section along line II-II′ of FIG. 4A.

FIG. 5A is an intermediate plan view of a flash memory of an embodiment of the invention.

FIG. 5B is a cross section along line I-I′ of FIG. 5A.

FIG. 5C is a cross section along line II-II′ of FIG. 5A.

FIG. 6A is an intermediate plan view of a flash memory of an embodiment of the invention.

FIG. 6B is a cross section along line I-I′ of FIG. 6A.

FIG. 6C is a cross section along line II-II′ of FIG. 6A.

FIG. 7A is an intermediate plan view of a flash memory of an embodiment of the invention.

FIG. 7B is a cross section along line I-I′ of FIG. 7A.

FIG. 7C is a cross section along line II-II′ of FIG. 7A.

FIG. 8A is an intermediate plan view of a flash memory of an embodiment of the invention.

FIG. 8B is a cross section along line I-I′ of FIG. 8A.

FIG. 8C is a cross section along line II-II′ of FIG. 8A.

FIG. 8D is a local three-dimensional view of FIG. 8A.

### DETAILED DESCRIPTION

Embodiments of the invention, which provides a method for forming a tip, will be described in greater detail by referring to the drawings that accompany the invention. It is noted that in the accompanying drawings, like and/or corresponding elements are referred to by like reference numerals.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers.

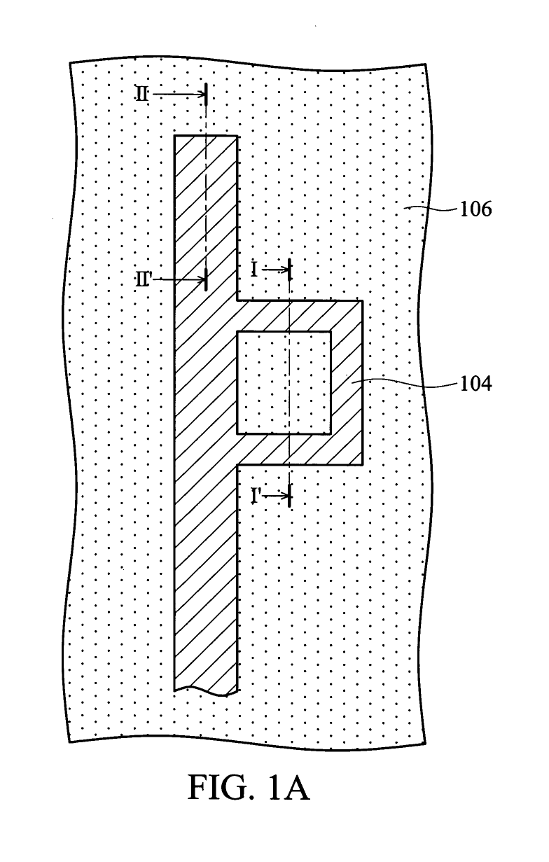

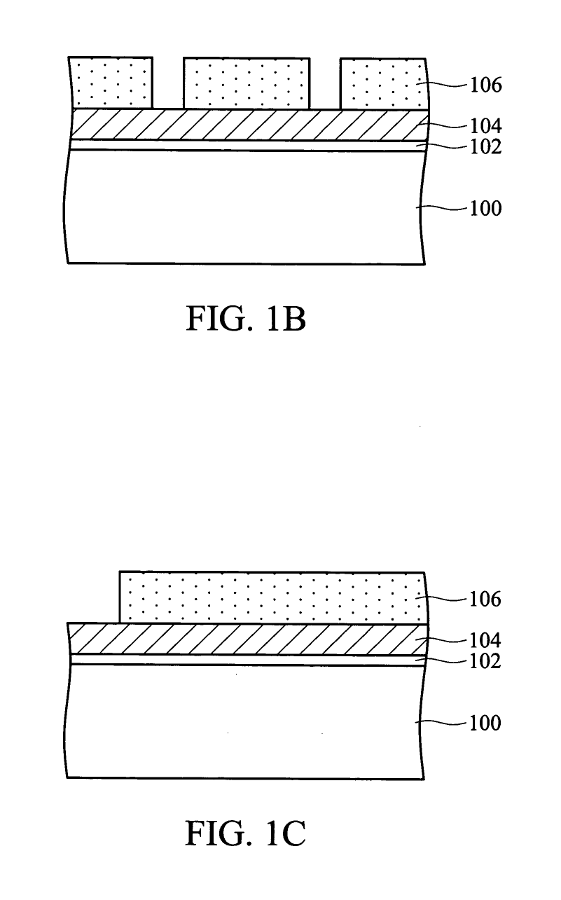

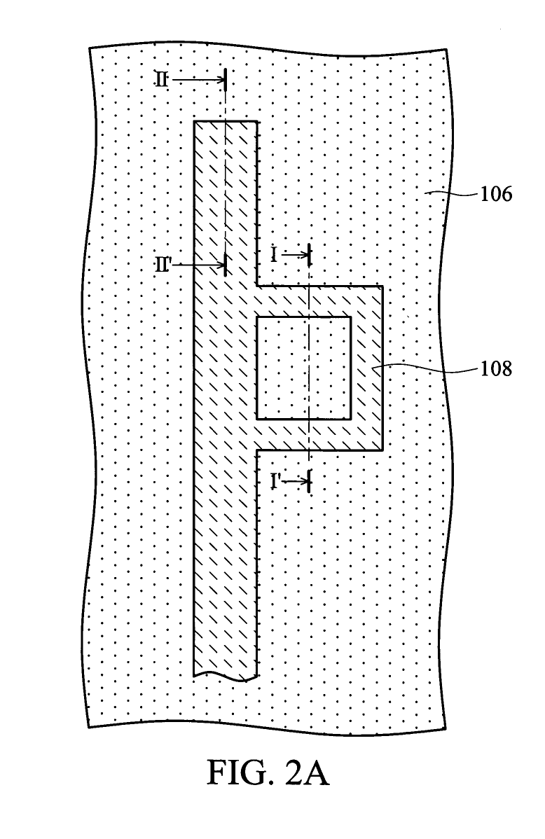

FIGS. 1A˜4C demonstrate a method known to the inventor of forming a contact to a ploy gate in a flash memory fabrication. This is not prior art for the purpose of determining the patentability of the present invention. This merely shows a problem found by the inventors.

FIG. 1A is an intermediate plan view of a flash memory. FIG. 1B is a cross section along line I-I′ of FIG. 1A. FIG. 1C is a cross section along line II-II′ of FIG. 1A. Referring to FIG. 1A, FIG. 1B and FIG. 1C, a gate dielectric layer 102, such as silicon oxide, is formed on a silicon substrate 100. A gate layer 104, for example polysilicon, is formed on the gate dielectric layer 102. A mask layer 106, such as silicon nitride, is formed on the gate layer 104.

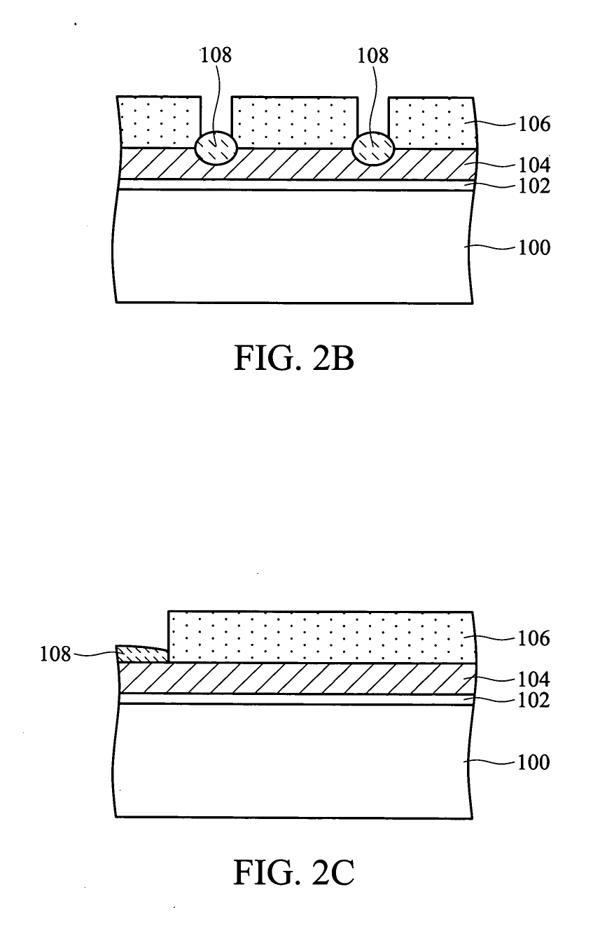

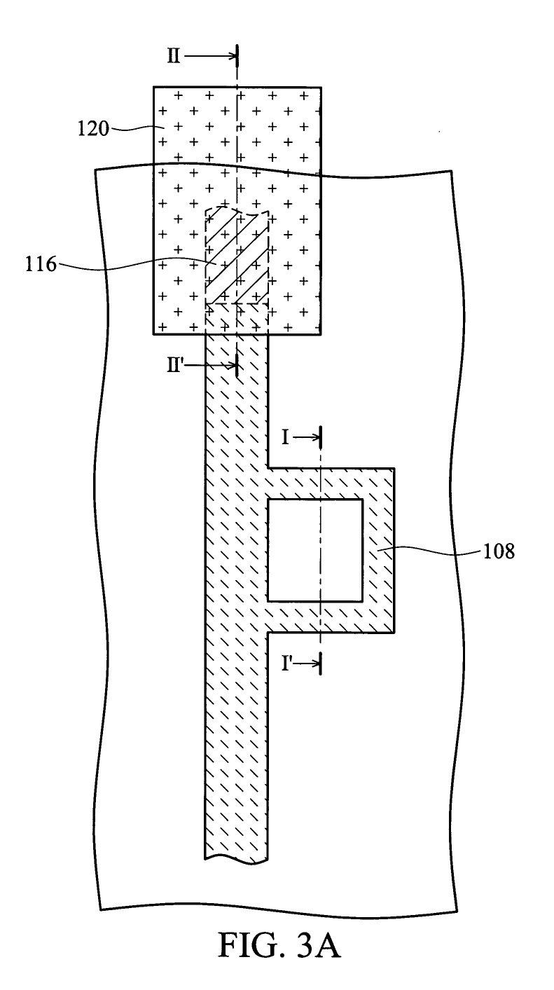

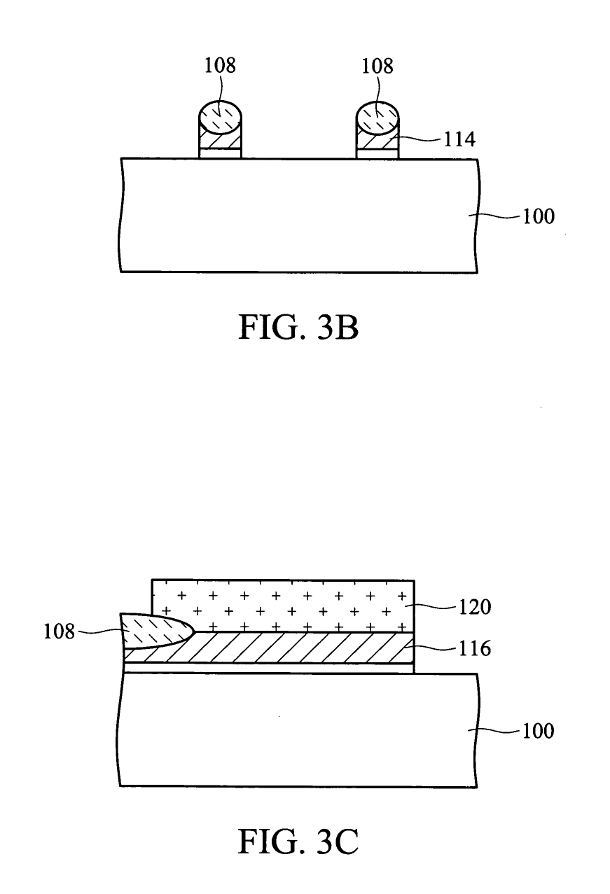

The mask layer 106 is patterned using conventional lithography and etching to expose a portion of the gate layer 104, predetermining a contact portion of a floating gate. Next, referring to FIG. 2A, FIG. 2B and FIG. 2C, the exposed gate layer is oxidized to form oxide masks 108 using the patterned mask layer 106 as a mask. Thereafter, referring to FIG. 3A, FIG. 3B and FIG. 3C, the mask layer 106 is removed, and the gate layer 104 is etched using the oxide mask 108 as a mask to form a contact portion of a floating gate, further comprising an non-contact portion.

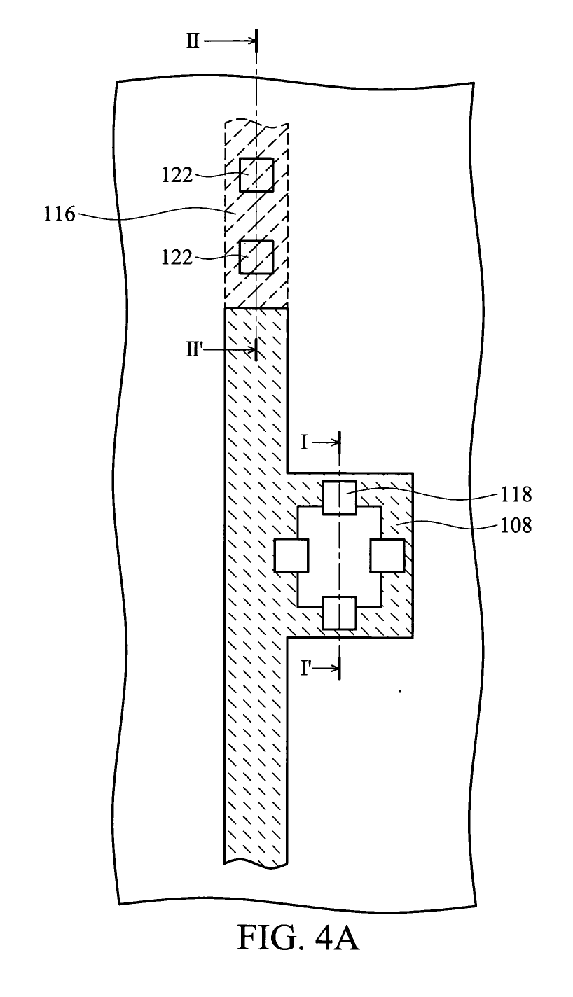

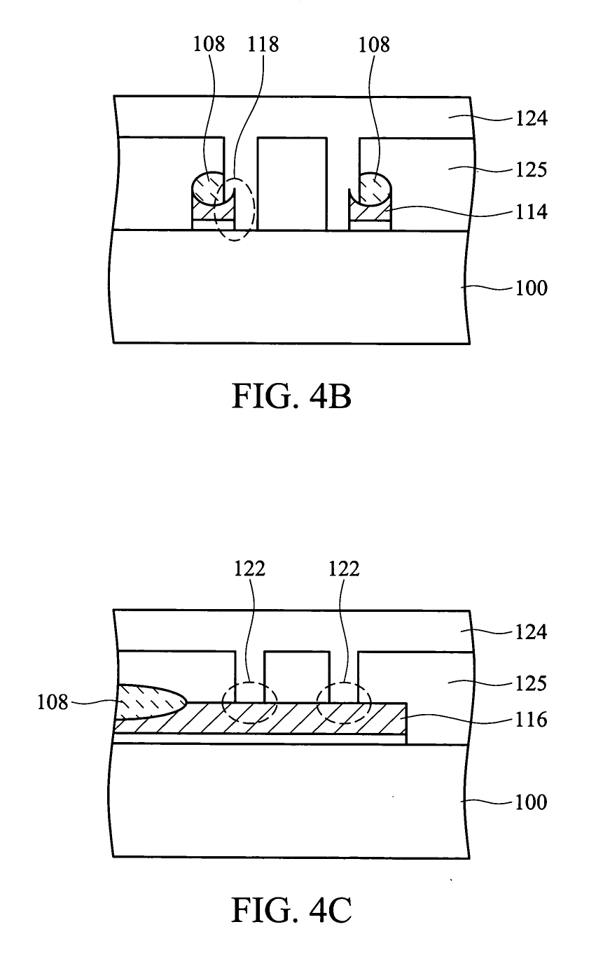

Referring to FIG. 3A, FIG. 3B, FIG. 3C, FIG. 4A, FIG. 4B and FIG. 4C, in general, the contact portion of the floating gate comprises a tip region 114 and a flat region 116. Due to insufficient contact area of only one side 118 of the tip region 114, additional lithography step is required to form a protective mask 120, leaving a further flat contact portion 122 of the floating gate for contacting metal lines 124 between inter metal dielectric layers 125.

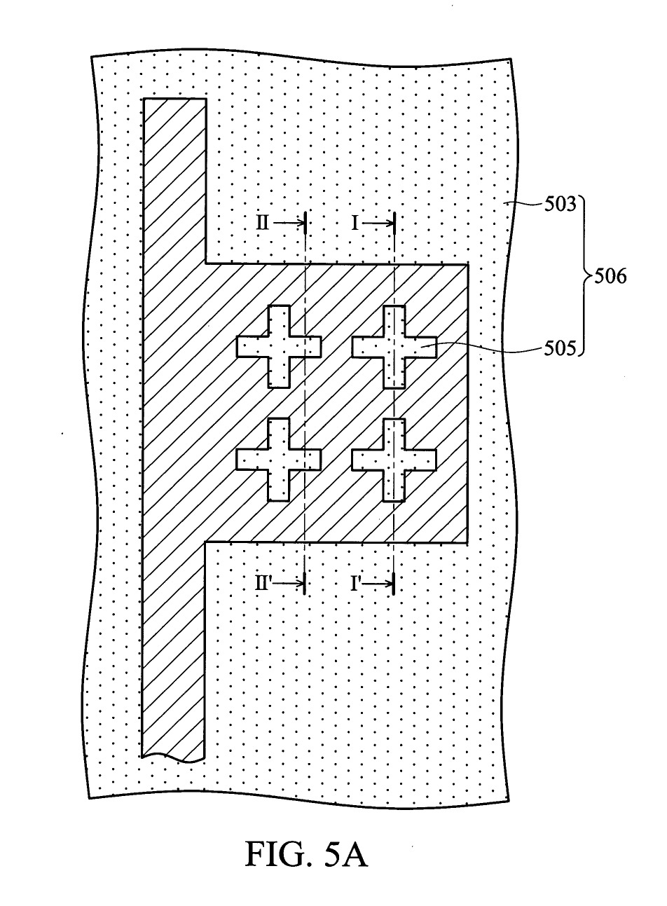

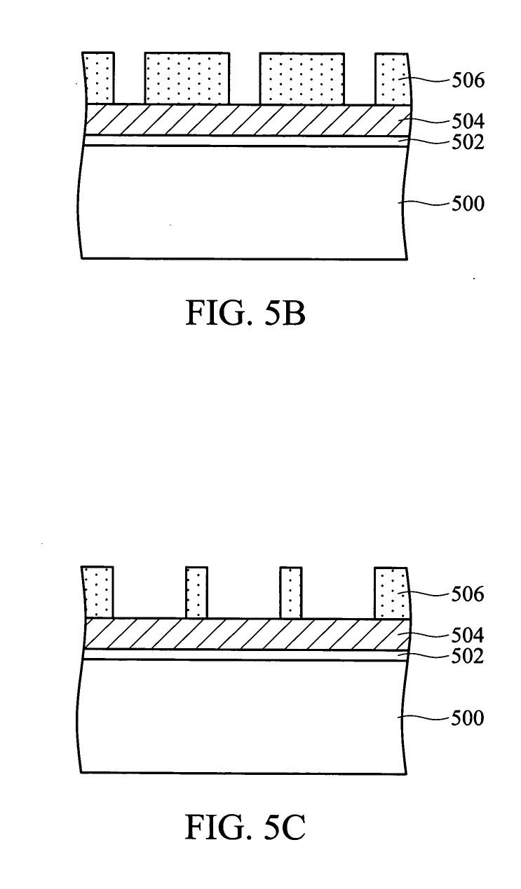

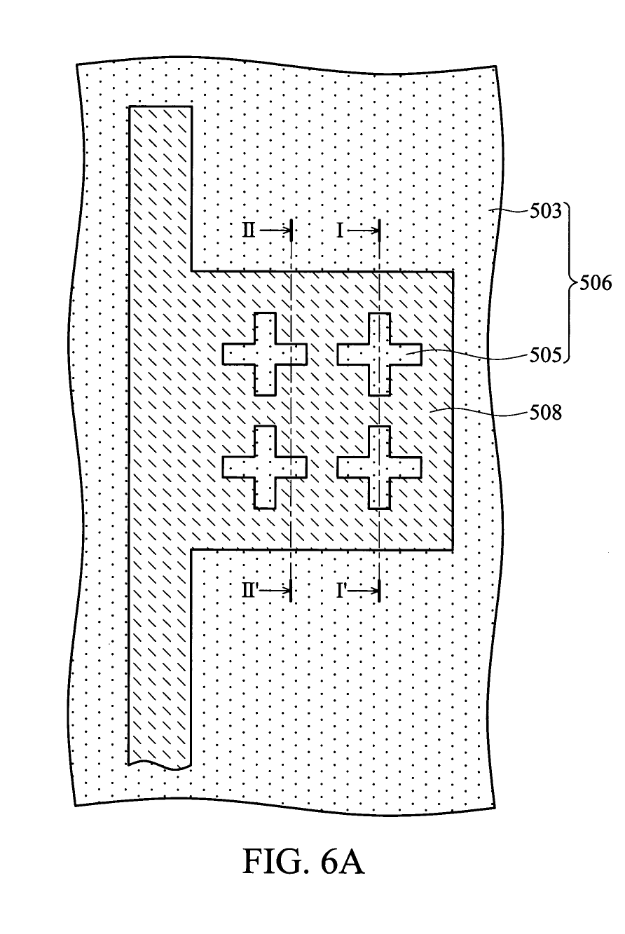

FIG. 5A is an intermediate plan view of a flash memory of an embodiment of the invention. FIG. 5B is a cross section along line I-I′ of FIG. SA, and FIG. 5C is a cross section along line II-II′ of FIG. 5A. Referring to FIG. 5A, FIG. 5B and FIG. 5C, a gate dielectric layer 502, such as silicon oxide, silicon nitride, silicon oxynitride, combination thereof, stacked layers thereof, or any other high k dielectric layer, is formed on a substrate 500. In one embodiment of the invention the gate dielectric layer 502 is a tunneling dielectric layer of a flash memory. The substrate 500 may comprise silicon, gallium arsenide, gallium nitride, strained silicon, silicon germanium, silicon carbide, diamond, an epitaxy layer, and/or other materials. A gate layer 504, for example polysilicon, SiGe, epitaxial silicon or any other semiconductor layer, is formed on the gate dielectric layer 502. A mask layer 506, such as silicon nitride, silicon oxynitride, or combination thereof, is formed on the gate layer 504. In one embodiment of the invention, the gate layer comprises polysilicon, and the mask layer comprises silicon nitride.

The mask layer 506 is patterned using conventional lithography and etching to form a mask pattern 506 comprising an inner portion 505 and an outer portion 503, predetermining a contact portion of a floating gate. The inner portion 505 is surrounded by the outer portion 503 of the mask pattern 506. In an embodiment of the invention, the inner portion 505 comprises a plurality of lines, preferably having width about 50˜500 nm. The lines may intersect or not, and when intersecting, may extend in any direction. In one embodiment of the invention, two intersected lines are perpendicular, and particularly the lines intersect to form a cross shape. The invention, however, is not limited thereto.

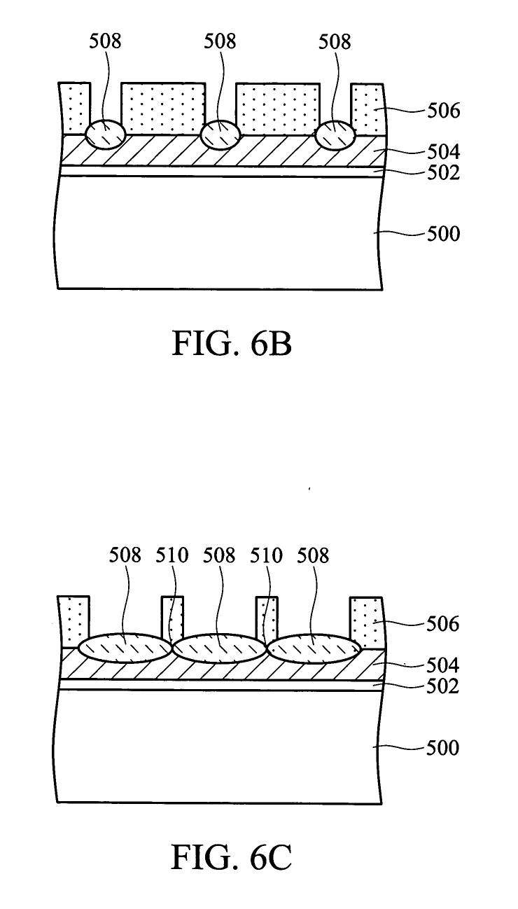

Next, referring to FIG. 6A, FIG. 6B and FIG. 6C, the exposed gate layer is reacted to form a reaction mask 508 using the mask pattern 506 as a mask. Under the inner portion 505 of the mask pattern 506, two adjacent portions of the reaction mask 508 connect to form a tip 510 due to bird beak effect. Consequently, the tip 510 is volcano-shaped. In one embodiment of the invention, the reaction mask 508 is a field oxide layer and the tip 510 is bird beak at edges of the field oxide layer.

In an embodiment of the invention, the reaction for forming the reaction mask 508 may comprise thermal process and plasma process. The thermal process may be an annealing process with O₂ as a reactive gas. The annealing treatment is preferably carried out at about 700° C. to about 1200° C., from about 1 Vol % to about 50 Vol % of O₂ with the remaining portion made up of H₂, for a period of from about 5 minutes to about 30 minutes. Following annealing treatment, the process wafer may additionally be cooled in the presence of N₂ containing ambient.

Alternatively, the annealing treatment may be carried out in two steps. For example, the substrate may be initially placed in a thermal processing furnace or rapid thermal processing chamber. In a first oxidation step, the chamber temperature is ramped up to typically about 700˜900° C. in an H ambient for typically about 10˜100 sec., to promote migration of silicon along the gate layer surfaces. In the second oxidation step, the chamber temperature is ramped up to typically about 1000˜1100° C. in an O₂ ambient to facilitate oxidation of the silicon along the gate layer surfaces. Depending on the particular application, the thickness range for the reaction masks is typically about 1000 Å˜10000 Å.

In an exemplary plasma treatment, the substrate is subjected to a plasma assisted treatment including plasma-source gases including O₂, O₃, or combinations thereof.

In addition, an inert gas such as He and Ar may be included in the mixture to assist formation of the plasma. The plasma is preferably formed as a high density plasma. For example, the plasma may be generated by conventional plasma sources such as helicon, helical-resonator, electron-cyclotron resonance, or inductively coupled. For example, using an ICP (inductively coupled plasma) source, an RF power of about 100 W to about 1000 W suitable. An RF or DC bias may be optionally applied to the process wafer surface to increase the rate of oxide layer growth. Preferably, the plasma assisted surface treatment is carried out at pressures on of about 1 mTorr to about 10 Torr, more preferably from about 100 mTorr to about 5 Torr at about 0° C. to about 400° C., for about 30 seconds to about 300 seconds.

In one embodiment of the invention, the reaction masks are silicon oxide and formed by thermal oxidation. The height of the tip 510 may be defined by thickness of the reaction masks 508, and is a design choice depending upon production requirements or process window.

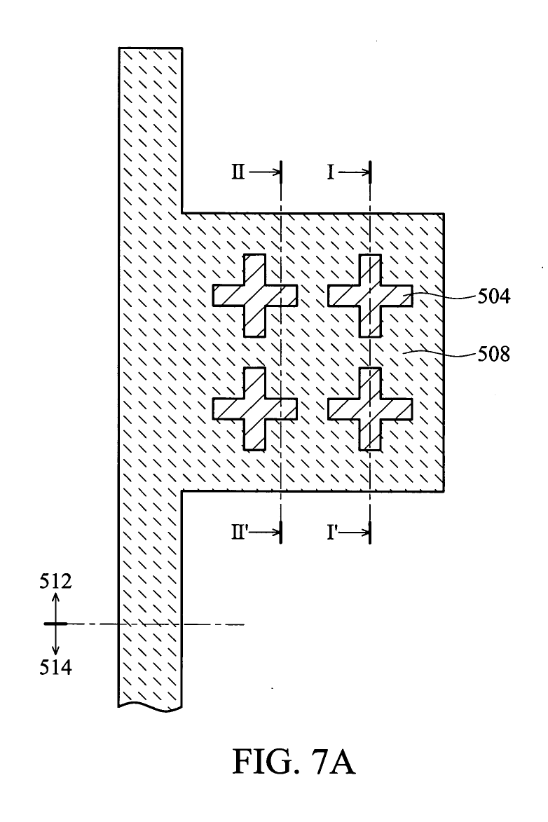

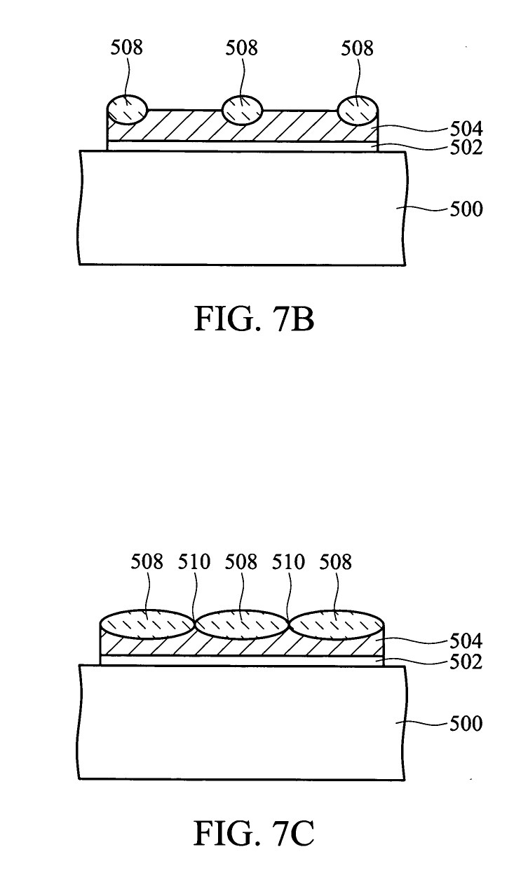

FIG. 7A is an intermediate plan view of a flash memory of an embodiment of the invention. FIG. 7B is a cross section along line I-I′ of FIG. 7A. FIG. 7C is a cross section along line II-II′ of FIG. 7A.

Referring to FIG. 7A, FIG. 7B and FIG. 7C, the mask layer 506 is removed. When the mask layer 506 is silicon nitride, removal of the mask layer 506 may be accomplished by wet etching, such as immersion in phosphoric acid or dry etching having good selectivity with nitride and oxide, for example dry etching using SF₆ and He as a process gas. In one embodiment of the invention, etching of the mask layer is accomplished by immersion in phosphoric acid, and more preferably the process temperature is about 180˜210° C., and the concentration is about 85%˜95%.

Thereafter, the gate layer 504 is etched using the reaction masks 508 as a mask to form the contact portion 512 of the gate, further comprising a non-contact portion 514. In one embodiment of the invention, the gate is a floating gate of a flash memory. When the reaction masks 508 comprise silicon oxide, the etching herein preferably has good selectivity between silicon oxide and polysilicon, for example a dry etching using Cl₂ or HCl as a main etchant, or another dry etching using HBr and O₂ as a main etchant.

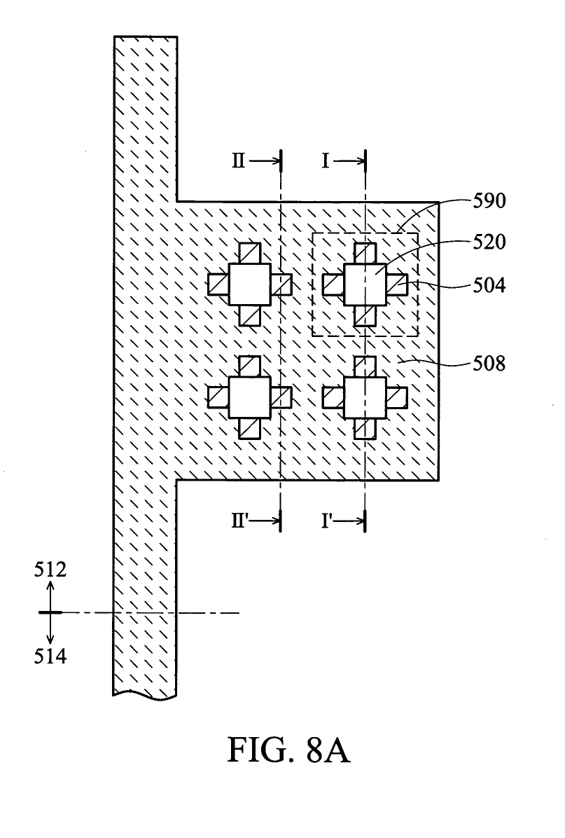

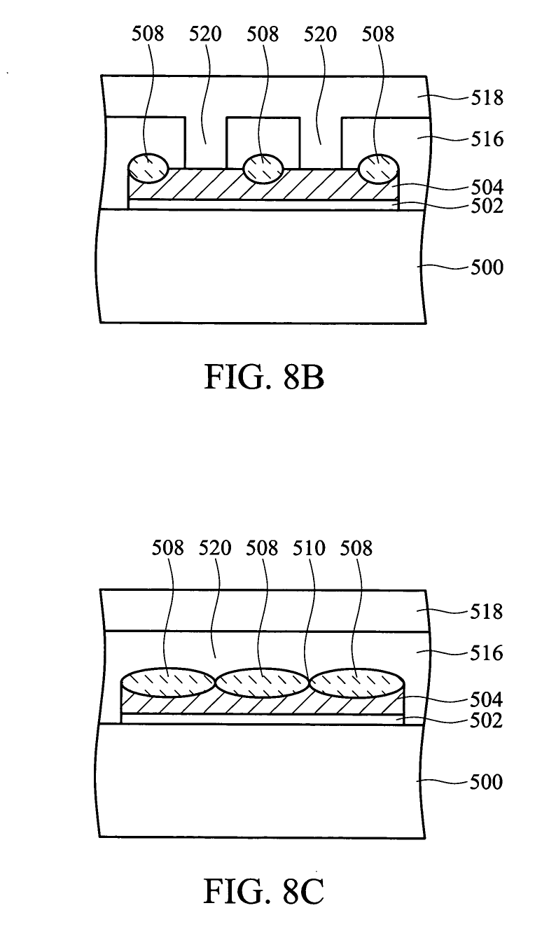

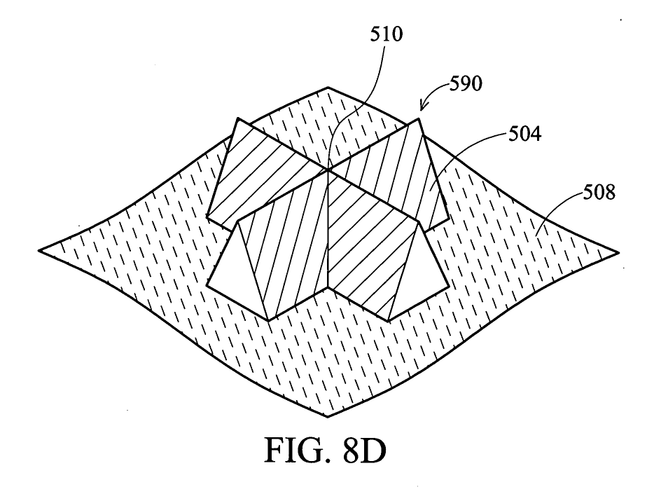

FIG. 8A is an intermediate plan view of a flash memory of an embodiment of the invention. FIG. 8B is a cross section along line I-I′ of FIG. 8A. FIG. 8C is a cross section along line II-II′ of FIG. 8A.

Referring to FIG. 8A, FIG. 8B and FIG. 8C, a dielectric layer 516 is formed on the reaction masks 508, the floating gate 504 and the substrate 500. The dielectric layer 516 may be formed by CVD, PECVD, ALD, PVD, spin-on coating and/or other processes. The dielectric layer may be an inter-metal dielectric (IMD), and may include silicon dioxide, polyimide, spin-on-glass (SOG), fluoride-doped silicate glass (FSG), Black Diamond (a product of Applied Materials of Santa Clara, Calif.), Xerogel, Aerogel, amorphous fluorinated carbon, and/or other materials. In an embodiment, the dielectric layer may include a low-k material having a dielectric constant k of less than about 3.3. For example, the dielectric layer may include an organic low-k material, CVD low-k material, and/or other suitable materials.

Next, the dielectric layer 516 is patterned by conventional photolithography and etching to form openings exposing the tips 510. Thereafter, a conductive layer 518 is blanketly deposited on the dielectric layer 516 and fills the openings to form a conductive plug 520.

The conductive layer 518 may be a single-metal layer, a dual-metal structure or a multi-layered structure selected from at least one of W, WNₓ, Ti, TiWₓ, TiNₓ, Ta, TaNₓ, Mo, Al, Cu, and the like. Any of a variety of deposition techniques, including, but not limited to, CVD, PVD, evaporation, plating, sputtering, reactive co-sputtering or combinations thereof, may allow the production of the metal layer.

FIG. 8D is a local three-dimensional view of FIG. 8A. As shown in FIG. 8D, in the local area 590, hill lines along two direction of the floating gate 504 intersect at the tip 510, which is connected to the conductive layer 518. In the konwn art, due to insufficient area of one side poly tip formed by self-aligned etching, additional lithography is required to form a contact to a floating gate. The tips 510 formed by the method of an embodiment of the invention are disposed in the inner portion of the floating gate, having sufficient contact areas, such that additional lithography for contacting can be omitted.

The invention, however, is not limited to the field of semiconductor device. The invention is also applied to photoelectric field to form tips using bird beak effect formed by field oxidation. For example, the method may be used to form tips in field emission display.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a tip, comprising:
providing a substrate;
forming a layer overlying the substrate;
forming a mask layer overlying the layer;
patterning the mask layer to form a mask pattern comprising an inner portion and an outer portion; and
reacting the layer uncovered by the mask pattern to form a reaction mask on the layer, wherein at least one portion of the reaction mask forms a tip of the layer under the inner portion of the mask pattern.

2. The method as claimed in claim 1, wherein the step of reacting the layer uncovered by the mask pattern is accomplished by oxidation.

3. The method as claimed in claim 1, wherein the reaction mask is a field oxide layer and the tip is bird beak at edge of the field oxide layer.

4. The method as claimed in claim 1, wherein the layer is a floating gate layer of a flash memory.

5. The method as claimed in claim 1, wherein the inner portion of the mask pattern comprises lines.

6. The method as claimed in claim 5, wherein at least two lines intersect with each other.

7. The method as claimed in claim 1, wherein the tip is volcano shaped.

8. The method as claimed in claim 1, wherein the tip is a tip of a field emission display.

9. A method for forming a contact to a gate, comprising:
providing a substrate;
forming a gate layer overlying the substrate, wherein the gate layer comprises a contact portion and a non-contact portion;
forming a mask layer overlying at least the contact portion of the gate layer;
patterning the mask layer to form a mask pattern comprising an outer portion and an inner portion, wherein the inner portion is surrounded by the outer portion; and
reacting the gate layer uncovered by the mask pattern to form a reaction mask, wherein the reaction mask forms a tip of the gate layer under the inner portion of the mask pattern.

10. The method as claimed in claim 9, wherein the step of reacting the gate layer uncovered by the mask pattern is accomplished by oxidation.

11. The method as claimed in claim 9, wherein the reaction mask is a field oxide layer and the tip is bird beak at edges of the field oxide layer.

12. The method as claimed in claim 9, wherein the gate layer is a floating gate layer of a flash memory.

13. The method as claimed in claim 9, wherein the inner portion of the mask pattern comprises lines.

14. The method as claimed in claim 9, wherein the inner portion of the mask pattern is cross shaped.

15. The method as claimed in claim 9, wherein the tip is volcano shaped.

16. A flash memory, comprising:
a substrate;
a tunneling dielectric layer overlying the substrate;
a floating gate overlying the tunneling dielectric layer, wherein the floating gate comprises a contact portion and a non-contact portion, the contact portion of the floating gate comprises at least a tip not adjacent to edges of the floating gate of the floating gate; and
a conductive plug contacts the floating gate at the tip.

17. The flash memory as claimed in claim 16, wherein the tip is volcano shaped.

18. The flash memory as claimed in claim 16, further comprises field oxide layers on the floating gate, wherein the tip is bird beak at edges of field oxide layers.
